(19) United States
(12) Patent Application Publication
(10) Pub. No.: US 2025/0316955 A1
(43) Pub. Date: Oct. 9, 2025

(54) HIGH-POWER DRIVER FOR WIDEBAND OPTICAL WIRELESS COMMUNICATIONS

(71) Applicant: QUALCOMM Incorporated, San Diego, CA (US)

(72) Inventors: Karoly BECZE, Escondido, CA (US); Yisheng XUE, San Diego, CA (US); Xiaoxia ZHANG, San Diego, CA (US); Junyi LI, Greentown, PA (US); Morteza SOLTANI, San Diego, CA (US); Sam LIU, San Diego, CA (US)

(21) Appl. No.: 18/628,270

(22) Filed: Apr. 5, 2024

(51) Int. Cl. H01S 5/042; H01S 5/00; H01S 5/02255; H03F 3/19

(52) U.S. Cl. CPC H01S 5/042; H01S 5/0092; H01S 5/02255; H03F 3/19; H03F 2200/451

(57) ABSTRACT

An apparatus, comprising: a radio frequency (RF) amplifier; and an RF-to-optical (RF2O) driver, comprising: a transformer chain including a set of cascaded RF transformers; and an impedance matching circuit coupled in series with the transformer chain between the RF amplifier and a laser.

### FIELD

This invention relates to optical wireless communication, and in particular, to a high-power driver for wideband optical wireless communications.

### BACKGROUND

An optical wireless communication system may facilitate data communication between user equipment (UE) using optical signals. Optical signals may be desirable in certain applications, for example, where high bandwidths/data rates (e.g., one tera bits per second (1 Tbps) per link) may be desirable. Such high data rates may be useful in some indoor or relatively short distance applications, such as multimedia, virtual/augmented reality (XR), holographic telepresence, asset tracking, factory communication, and others. It may also be desirable for such optical wireless communication systems to interface with radio frequency (RF) systems, such as those used in wideband wide area networks (WWANs) (e.g., Fifth Generation (5G) New Radio (NR) and/or Sixth Generation (6G) compliant WWANs).

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes: a radio frequency (RF) amplifier; and an RF-to-optical (RF2O) driver, comprising: a transformer chain including a set of cascaded RF transformers; and an impedance matching circuit coupled in series with the transformer chain between the RF amplifier and a laser.

Another aspect of the disclosure relates to method. The method includes: transforming a first complex impedance related to a diffused laser into a first substantially real impedance; and transforming the first substantially real impedance into a second substantially real impedance related to a radio frequency (RF) amplifier via a set of cascaded RF transformers.

Another aspect of the disclosure relates to an optical communication device. The optical communication device, comprises: a modem; one or more frequency upconverting stages coupled to the modem; a local oscillator (LO) coupled to the one or more frequency upconverting stages; a radio frequency (RF) amplifier coupled to the one or more frequency upconverting stages; a diffused laser; and an RF-to-optical (RF2O) driver, including: a transformer chain including a set of cascaded RF transformers; and an impedance matching circuit coupled in series with the transformer chain between the RF amplifier and the diffused laser.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example optical wireless communication system in accordance with an aspect of the disclosure.

FIG. 2 illustrates a block diagram of an example optical wireless transceiver in accordance with another aspect of the disclosure.

FIG. 3 illustrates a block diagram of an example radio frequency to optical (RF2O) driver in accordance with another aspect of the disclosure.

FIG. 4 illustrates a schematic diagram of an example radio frequency (RF) transformer chain in accordance with another aspect of the disclosure.

FIG. 5 illustrates a schematic diagram of an example impedance matching circuit in accordance with another aspect of the disclosure.

FIG. 6 illustrates a schematic diagram of an example bias tee in accordance with another aspect of the disclosure.

FIG. 7 illustrates a block diagram of another example radio frequency to optical (RF2O) driver in accordance with another aspect of the disclosure.

FIG. 8 illustrates a schematic diagram of an example standing wave ratio (SWR) sensor in accordance with another aspect of the disclosure.

FIG. 9 illustrates a schematic diagram of an example configurable radio frequency (RF) transformer chain in accordance with another aspect of the disclosure.

FIG. 10 illustrates a schematic diagram of an example tunable impedance matching circuit in accordance with another aspect of the disclosure.

FIG. 11 illustrates a side view of an example high-intensity diffused (HID) laser in accordance with another aspect of the disclosure.

FIG. 12 illustrates a block diagram of an example radio frequency to optical (RF2O) interface in accordance with another aspect of the disclosure.

FIG. 13 illustrates a flow diagram of an example method of impedance matching an output impedance of a radio frequency (RF) amplifier to an input impedance of a laser in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts. The term “substantially” means that the associated parameter (e.g., impedance) may not be exact as indicated but accounts for some variation due to specified tolerances.

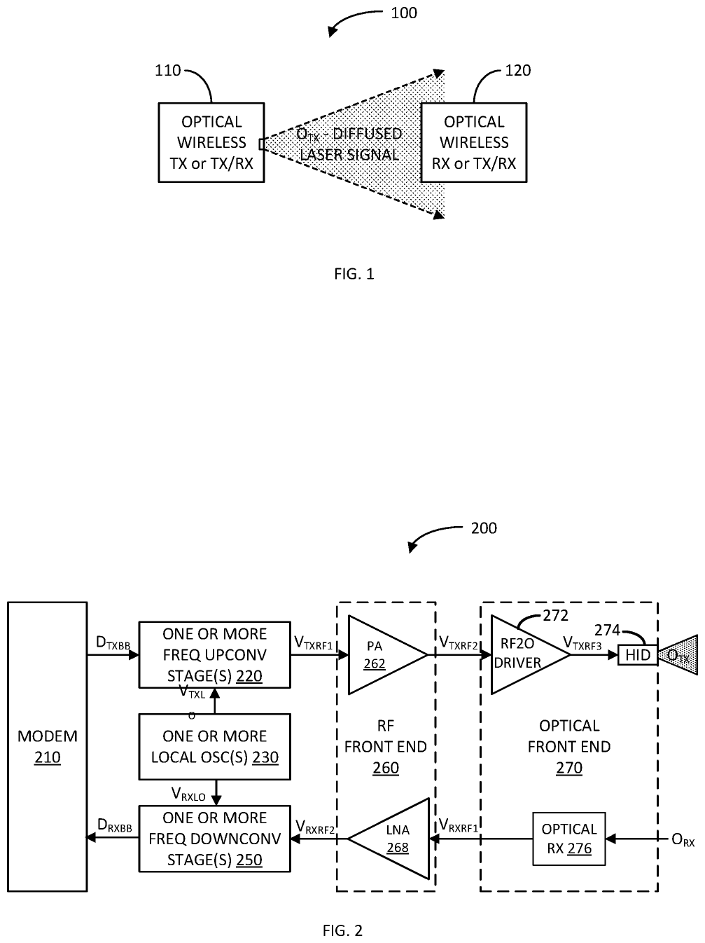

FIG. 1 illustrates a block diagram of an example optical wireless communication system (or network) 100 in accordance with an aspect of the disclosure. The optical wireless communication system 100 includes an optical wireless transmitter (Tx) or transceiver (Tx/Rx) 110 and an optical wireless receiver (Rx) or Tx/Rx 120. The optical wireless Tx or Tx/Rx 110 and optical wireless Rx or Tx/Rx 120 may be implemented in user equipment (UE), access points, or base stations (e.g., a gNB or the like). Depending on the technology of the network 100, a base station 110 may comprise a node B, an Evolved Node B (eNodeB or eNB), a base transceiver station (BTS), a radio base station (RBS), an NR NodeB (gNB), a Next Generation eNB (ng-eNB), or the like. A base station 110 that is a gNB or ng-eNB may be part of a Next Generation Radio Access Network (NG-RAN) which may connect to a 5G Core Network (5GC) in the case that Network 110 is a 5G or 6G network. The system or network 100 may be part of a free-space optical wireless local area network (WLAN) or wireless wide area network (WWAN) communication system including UE/gNB, which include some benefits as higher data rates, lower latencies, immunity to electromagnetic interference (EMI), and others. As previously mentioned, the optical wireless communication system 100 may be part of an indoor or relatively short distance (e.g., <300 meters (m)) data communication system; however, it neither be limited to indoor nor short distance applications.

To effectuate communication between the Tx or Tx/Rx 110 and the optical wireless Rx or Tx/Rx 120, the optical wireless communication Tx or Tx/Rx 110 generates a radio frequency (RF)-modulated optical transmit signal O_{TX} using a high-intensity diffused (HID) laser for transmission to the optical wireless communication Rx or Tx/Rx 120. The RF modulation signal may be compliant with various WWAN standards (e.g., 5G NR or 6G), and may have a relatively high percent bandwidth (e.g., 67%). As an example, the RF modulation signal may have a bandwidth of 400 megaHertz (MHz) with a center frequency of 600 MHz. Accordingly, an RF signal processing front-end may interface with the HID laser.

Furthermore, the HID laser may have a relatively small impedance (e.g., around less than three (3) Ohms (Q)), and may also be complex due to inductive wire bonds and capacitive die and/or package parasitic. As most RF signal processing circuits are configured for 50Ω signal transmission, interfacing an RF signal processing front end to an HID laser creates challenges. Such challenges may be further exacerbated by the relatively high-power laser requirement for the HID laser to achieve, for example, a signal transmission of 300 m with a power density of 300 milliWatts per meter squared (mW/m²). In such application, the HID laser may draw an operating current of greater than one amperes (1 A).

FIG. 2 illustrates a block diagram of an example optical wireless transceiver 200 in accordance with another aspect of the disclosure. The optical wireless transceiver 200 may be an example transceiver (Tx/Rx) implemented in any of the optical wireless Tx or Tx/Rx 110 and/or optical wireless Rx or Tx/Rx 120. In particular, the optical wireless transceiver 200 includes a modem 210, one or more frequency upconverting stage(s) 220, one or more local oscillator(s) 230, one or more frequency downconverting stage(s) 250, a radio frequency (RF) front end 260, and an optical front end 270.

With regard to signal transmission, the modem 210 is configured to generate a transmit baseband signal D_{TXBB}. The one or more frequency upconverting stage(s) 220 is configured to frequency upconvert the transmit baseband signal D_{TXBB} (e.g., from baseband (BB) to radio frequency (RF) directly or via one or more intermediate frequencies (IFs)) using one or more transmit local oscillator signal(s) V_{TXLO} generated by the one or more local oscillator(s) 1130 to generate a first transmit RF signal V_{TXRFlI}. Although the RF signals described herein are labeled with a leading V to indicate voltage, it shall be understood that the RF signals may also be currents. The RF front end 260 includes a power amplifier (PA) 262 configured to amplify the first transmit RF signal V_{TXRF2} to generate a second transmit RF signal V_{TXRF2}. Although the PA 262 serves as an example for explaining the concepts herein, it shall be understood that the PA may be any RF amplifier, such as a pre-amplifier, driver amplifier, or other.

The optical front end 270 may include a radio frequency to optical (RF2O) driver 272 and a high-intensity diffused (HID) laser 274. The RF2O driver 272 is configured to generate an RF modulation signal V_{TXRX3} for the HID laser 274 based on the second transmit RF signal V_{TXRX2}. As previously mentioned, the PA 262 may have an output impedance of substantially 50Ω. Also, as previously mentioned, the HID laser 274 may have a relatively low input impedance (e.g., <3Ω). To reduce power losses in the form of reflected power as a result of the significant impedance mismatch between the output impedance of the PA 262 and the input impedance of the HID laser 274, the RF2O driver 272 performs a progressive impedance transformation from substantially 50Ω to <3Ω (or vice-versa), as discussed in more detail further herein. Additionally, since the HID laser 274 requires biasing (e.g., to be operated in linear mode for 5G/6G purposes), the RF2O driver 272 may include a bias tee for supplying a bias current (e.g., >1 A) as well as for providing the RF modulation signal V_{TXRF3} to the HID laser 274, while further configured to facilitate the impedance match between the output of the PA 262 and the input of the HID laser 274. The HID laser 274 is configured to generate an optical transmit signal O_{TX} modulated with the RF modulation signal V_{TXRX3} for transmission to one or more remote optical wireless devices.

With regard to optional signal reception, the optical front end 270 may further include an optical receiver 276 configured to generate a first received RF signal V_{RXRF1} based on a received optical signal O_{RX}. For example, the optical receiver 276 may include a silicon photomultiplier (SiPM), an avalanche photodiode, or other similar device configured to convert an optical signal into an electrical signal. The RF front end 260 may further include a low noise amplifier (LNA) 268 configured to amplify the first received RF signal V_{RXRF1} to generate a second received RF signal V_{RXRF2}.

The one or more frequency downconverting stage(s) 250 is configured to frequency downconvert the second received RF signal V_{RXRF2} (e.g., from RF to BB directly or via one or more IFs) using one or more received local oscillator signal(s) V_{RXLO} generated by the one or more local oscillator(s) 230 to generate a received BB signal D_{RXBB}. The modem 210 may receive and process the received BB signal D_{RXBB} to extract and/or recover information or data therein.

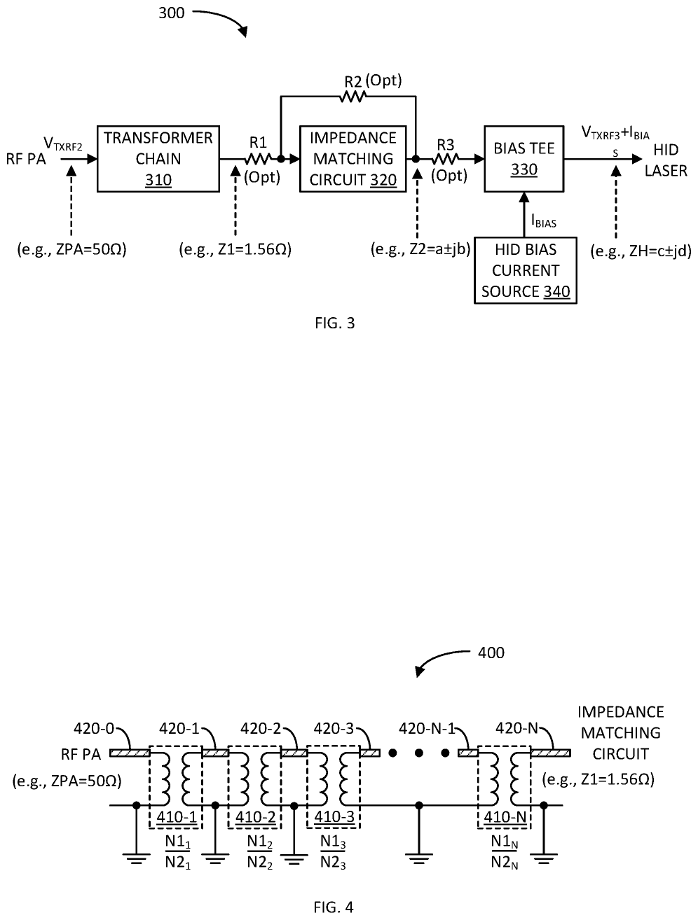

FIG. 3 illustrates a block diagram of an example radio frequency to optical (RF2O) driver 300 in accordance with another aspect of the disclosure. The RF2O driver 300 may be an example implementation of the RF2O driver 272 of optical wireless transceiver 200.

The RF2O driver 300 includes a transformer chain (e.g., a set of cascaded transformers) 310, an impedance matching circuit 320, a bias tee 330, and a high-intensity diffused (HID) laser current source 340. The transformer chain 310 includes an input coupled to an output of a radio frequency (RF) power amplifier (e.g., PA 262) to receive an amplified RF signal (e.g., V_{TXRF2}). As discussed further herein, the transformer chain 310 is further configured to perform a coarse impedance transformation between an impedance ZPA at the output of the PA (e.g., substantially 50Ω) and an impedance Z1 at the input of the impedance matching circuit 320 (e.g., a substantially low real impedance being substantially an integer divisor (e.g., 1/32) of the impedance ZPA, e.g., Z1=50Ω/32=1.56Ω)

The impedance transformation may be based on an effective or overall turns ratio of the transformer chain in accordance with the following relationship:

$$\frac{ZPA}{Z 1} = \frac{NE 1}{NE 2}$$

Where NE1 is the effective or cumulative primary winding turns, and NE2 is the effective or cumulative secondary winding turns. The effective turns ratio NE1/NE2 may be related to the individual turns ratio of a set of N cascaded RF transformers according to the following relationship:

$$\frac{NE 1}{NE 2} = {{\prod }_{k = 1}}^{N} \frac{N {1}_{k}}{N {2}_{k}}$$

Where N1ₖ/N2ₖ is the turns ratio for the kl cascaded RF transformer of the set of N cascaded RF transformers of the transformer chain 310. As an example, the transformer chain 310 may have an overall turns ratio of 1/2⁵ or 1/32 (e.g., five (5) cascaded RF transformers each with a turns ratio of one half (1/2)), which is configured to transform the ZPA=50Ω impedance at the output of the PA to the Z1=1.56Ω impedance at the input of the impedance matching circuit 320 (e.g., 50Ω/2⁵=50Ω/32=1.56Ω, wherein 1/32 is the effective or overall turns ratio of the transformer chain 310).

The impedance matching circuit 320 may be configured to transform a complex impedance Z2=a±jb at the input of the bias tee 330 into the substantially real impedance Z1 at the input of the impedance matching circuit 320. This facilitates the transformer chain 310 to transform the substantially real impedance (e.g., ZPA=50Ω) at the output of the PA into the real impedance (e.g., Z1=1.56Ω) at the input of the impedance matching circuit 320.

The bias tee 330 is configured to combine the RF signal received from the impedance matching circuit 320 with a bias current I_{BIAS} received from the HID laser bias current source 340 to provide an RF modulation signal (e.g., V_{TXRF3}) and a bias current I_{BIAS} for a HID laser (e.g., HID laser 274). Additionally, the bias tee 330 is further configured to impedance transform an inherent complex impedance ZH=c±jd of the HID laser to the complex impedance Z2=a±jb at the input of the bias tee 330 based on the operating RF frequency range of the RF2O driver 300 (e.g., 400-800 MHz).

An optional resistor R1 may be coupled between the transformer chain 310 and the impedance matching circuit 320. Alternatively, or in addition to, an optional resistor R2 may be coupled in parallel with the impedance matching circuit 320. The resistors R1 and/or R2 may be implemented to lower the quality factor (Q) of the impedance matching circuit 320 for greater bandwidth matching. Similarly, an optional resistor R3 may be coupled between the impedance matching circuit 320 and the bias tee 330. The resistor R3 may be implemented to lower the Q of the bias tee 330 for greater bandwidth matching.

FIG. 4 illustrates a schematic diagram of an example radio frequency (RF) transformer chain 400 in accordance with another aspect of the disclosure. The RF transformer chain 400 may be an example implementation of the RF transformer chain 310 of the RF2O driver 300 previously discussed.

The RF transformer chain 400 includes a set of cascaded RF transformers 410-1 to 410-N, where N is an integer of two (2) or more. The set of cascaded RF transformers may be cascaded directly without any intervening transmission lines. The RF transformer chain 400 may further include an input transmission line 420-0 coupled between the RF PA 262 and a first (e.g., upper) end of the primary winding of the first RF transformer 410-1 in the chain. Optionally, the RF transformer chain 400 may further include a set of one or more transmission lines 420-1 to 420-N−1 coupling first (e.g., upper) ends of the secondary-to-primary winding(s) of adjacent RF transformers 410-1/410-2 to 410-N−1/410-N, respectively. Further, the RF transformer chain 400 includes an output transmission line 420-N coupled between the first (e.g., upper) end of the secondary winding of the last RF transformer 420-N and the impedance matching circuit 320. If included, each of the transmission lines 420-0 to 420-N may be configured to have a particular characteristic impedance Zo, such as the impedance ZPA at the output of the PA 262 (e.g., 50Q). The second (e.g., lower ends) of the primary and secondary windings of the set of cascaded RF transformers 410-1 to 410-N may be coupled to ground.

Each of the cascaded RF transformers 410-1 to 410-N may be implemented with a set of turns ratio N1₁/N2₁ to N1_{N}/N2_{N} to effectuate the impedance transformation between the output of the PA 262 (e.g., ZPA=50Ω) and the input of the impedance matching circuit 320 (e.g., Z1=1.56Ω), respectively. As an example, each of the cascaded RF transformers 410-1 to 410-N may be configured with substantially the same turns ratio (e.g., each of N1₁/N2₁ to N1_{N}/N2_{N}=half (1/2)). In such case, if N=5, then the RF transformers 410-1 to 410-5 may each having a turns ratio of one half (1/2) with an effective turns ratio of 1/2⁵ or 1/32 to transform the ZPA=50Ω impedance at the output of the PA 262 into the Z1=1.56 impedance at the input of the impedance matching circuit 320 (e.g., 50Ω/25=50/32=1.56Ω). However, it shall be understood that the RF transformers 410-1 to 410-N may be configured with different turns ratios or a mix of the same and different turns ratios.

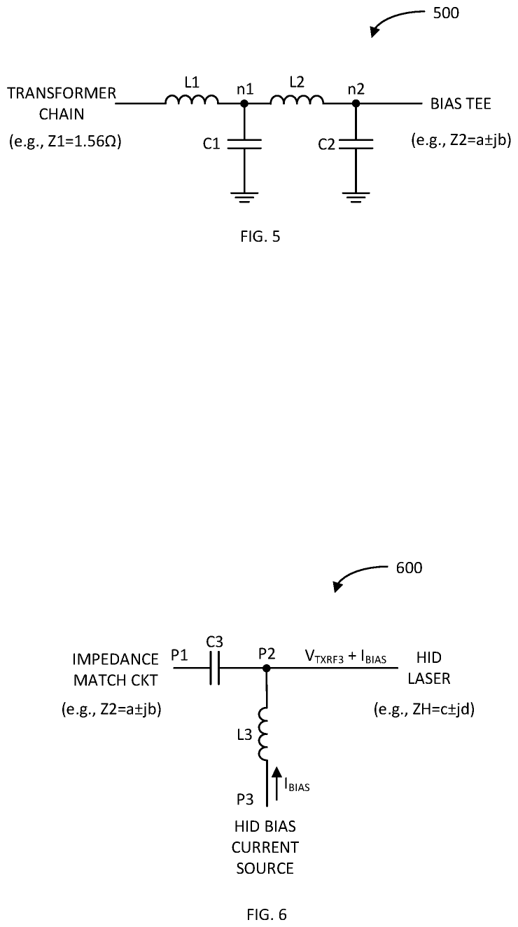

FIG. 5 illustrates a schematic diagram of an example impedance matching circuit 500 in accordance with another aspect of the disclosure. The impedance matching circuit 500 may be an example implementation of the impedance matching circuit 320 of RF2O driver 300 previously discussed.

The impedance matching circuit 500 may be implemented as a low pass filter (LPF). In particular, the impedance matching circuit 500 includes a first series inductor L1 coupled between the RF transformer chain 310 and a first node n1. The impedance matching circuit 500 further includes a first shunt capacitor C1 coupled between the first node n1 and ground. Further, the impedance matching circuit 500 further includes a second series inductor L2 coupled between the first node n1 and a second node n2. The impedance matching circuit 500 also includes a second shunt capacitor C2 coupled between the second node n2 and ground. The second node n2 may be coupled to the input of the bias tee 330. It shall be understood that the impedance matching circuit 500 may include at least one series inductor and at least one shunt capacitor.

As previously discussed, the impedance matching circuit 500 is configured to transform the complex impedance Z2=a±jb at the input of the bias tee 330 into a substantially real impedance Z1 at the output of the RF transformer chain 310. The inductances of inductors L1 and L2 and the capacitances of capacitors C1 and C2 may be set to effectuate the aforementioned impedance transformation. It shall be understood that the impedance matching circuit 500 may be implemented in different manners to perform the desired impedance transformation.

FIG. 6 illustrates a schematic diagram of an example bias tee 600 in accordance with another aspect of the disclosure. The bias tee 600 may be an example of the bias tee 330 of RF2O driver 300 previously discussed.

The bias tee 600 includes a capacitor C3 coupled between an input port P1 and an output port P2. The input port P1 may be coupled to an impedance matching circuit previously discussed. Additionally, the bias tee 600 includes an inductor L3 coupled between a third port P3 coupled to an HID laser current source previously discussed and the output port P2. As previously discussed, the bias tee 600 is configured to combine the RF signal received from the impedance matching circuit 320 or 500 and the bias current I_{BIAS} received from the HID laser current source 340 to provide an RF modulation signal V_{TXRX3} and the bias current I_{BIAS} to an HID laser. The capacitor C3 substantially blocks the bias current I_{BIAS} from flowing to the impedance matching circuit 320 or 500. The inductor L3 substantially blocks the RF modulation signal V_{TXRX3} from flowing into the output of the HID laser current source.

As previously discussed, the bias tee 600 may be configured to transform the inherent complex impedance ZH=c±jd of the HID laser to a complex impedance Z2=a±jb at the output of the impedance matching circuit 320 or 500 based on the operating RF frequency range. The capacitance of capacitors C3 and the inductance of inductor L3 may be set to effectuate the aforementioned impedance transformation. It shall be understood that the bias tee 600 may be implemented in different manners to perform the desired impedance transformation.

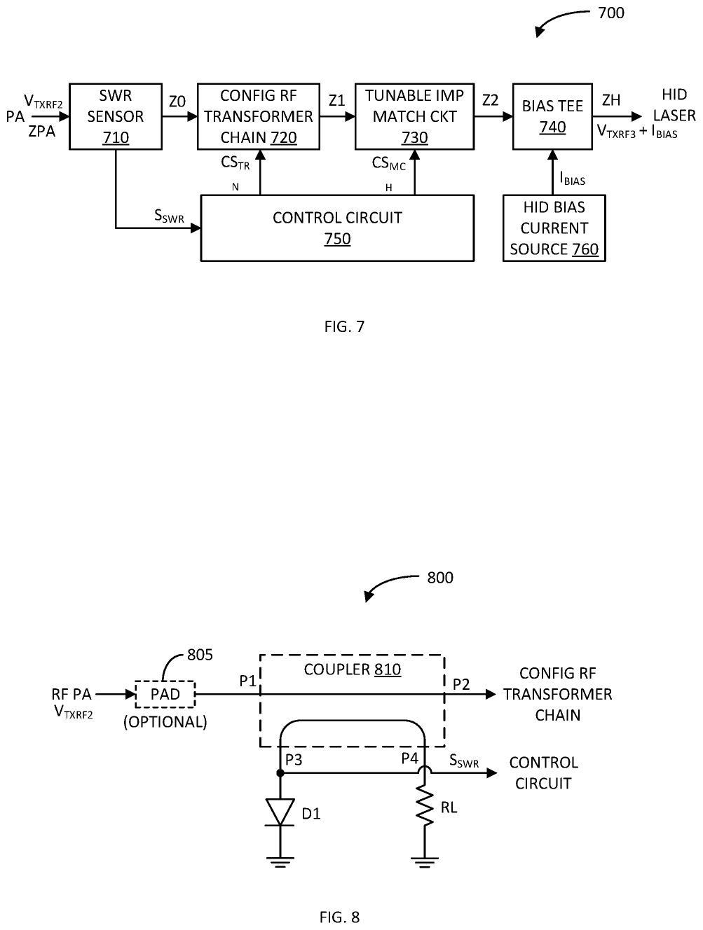

FIG. 7 illustrates a block diagram of another example radio frequency to optical (RF2O) driver 700 in accordance with another aspect of the disclosure. The RF2O driver 700 may be another example implementation of the RF2O driver 272 of optical wireless transceiver 200 previously discussed. The RF2O driver 700 includes a standing wave ratio (SWR) sensor 710, a configurable radio frequency (RF) transformer chain 720, a tunable impedance matching circuit 730, a bias tee 740, a high-intensity diffused (HID) laser current source 760, and a control circuit 750. Although not shown in FIG. 7, the RF2O driver 700 may optionally include one or more of the Q-lowering resistors similar to R1-R3 of RF2O driver 300.

The SWR sensor 710 (e.g., first and second ports) is coupled between a power amplifier (PA) (e.g., PA 262) and the configurable RF transformer chain 720. The RF transformer chain 720 (e.g., first and second ports), in turn, is coupled between the SWR sensor 710 and the tunable impedance matching circuit 730. The tunable impedance matching circuit 730 (e.g., first and second ports), in turn, is coupled between the configurable RF transformer chain 720 and the bias tee 740. The bias tee 740 (e.g., first and second ports), in turn, is coupled between the tunable impedance matching circuit 730 and an HID laser (e.g., HID laser 274). The HID laser current source 760 includes an output coupled to a third port of the bias tee 740. The control circuit 750 (e.g., microcontroller, microprocessor, processor, computing device, dedicated circuit, etc.) includes an input coupled to a third port of the SW sensor 710, and a pair of outputs coupled to respective third ports of the configurable RF transformer chain 720 and tunable impedance matching circuit 730.

The SWR sensor 710 is configured to generate a signal S_{SWR} at its third port related to the SWR at the output of the PA 262. As the third port of the SW sensor 710 is coupled to an input of the control circuit 750, the control circuit 750 receives the SWR signal S_{SWR}. The SWR at the output of the PA 262 is related to the impedance match between the PA and the configurable RF transformer chain 720. The higher the peak-to-peak amplitude of the SWR signal, the greater is the impedance mismatch between the PA and the configurable RF transformer chain 720. Conversely, the lower the peak-to-peak amplitude of the SWR signal, the lesser is the impedance mismatch between the PA and the configurable RF transformer chain 720. Accordingly, the control circuit 750 is configured to generate control signals CS_{TRN} and CS_{MCH} at its pair of outputs based on the signal S_{SWR}, respectively. The control circuit 750 may be configured to perform a process (e.g., a machine learning (ML) algorithm, such as Hill-Climbing or Gradient-Descent) to substantially minimize the signal S_{SWR}, which serves as a cost function for the process.

As the pair of outputs of the control circuit 750 are coupled to the respective third ports of the configurable RF transformer chain 720 and the tunable impedance matching circuit 730, the control signals CS_{TRN} and CS_{MCH} generated by the control circuit 750 adjust impedance transforming parameters of the configurable RF transformer chain 720 and the tunable impedance matching circuit 730, respectively.

With respect to the configurable RF transformer chain 720, the control signal CS_{TRN} may bypass one or more of the set of cascaded RF transformers of the RF transformer chain 720. As the number of cascaded RF transformers not bypassed affect the effective turns ratio NE1/NE2 of the transformer chain 720 as previously discussed, and the impedance ratio Z0/Z1 is related or substantially equal to the effective turns ratio NE1/NE2, the control circuit 750 is able to tune the configurable RF transformer chain 720 to improve the impedance matching between the PA and the configurable RF transformer chain 720 by reducing the signal S_{SWR}. As an example, if the substantially real impedance Z1 at the output of the configurable RF transformer chain 720 is 3.13Ω, and there are five (5) RF transformers in the chain, the control circuit 750 may generate the control signal CS_{TRN} to bypass one (1) of the RF transformers, where the four (4) remaining RF transformers, each having a turns ratio of one half (1/2), is able to transform the Z1=3.13Ω to Z0=ZPA=50Ω with an effective turns ratio of 1/24 or 1/16 (e.g., 50Ω/2⁴=50Ω/16=3.13Ω).

With respect to the tunable impedance matching circuit 730, the control signal CS_{MCH} may tune one or more of its capacitive or inductive elements to transform the complex impedance Z2 at the input of the bias tee 740 to the substantially real impedance Z1 at the output of the configurable RF transformer chain 720. In this regard, one or more of the inductors L1 and L2 and capacitors C1 and C2 of impedance matching circuit 500 may be made variable so that the control circuit 750 is able to tune the inductance and capacitance thereof to achieve the substantially real impedance Z1 at the output of the configurable RF transformer chain 720, as exemplified further herein.

The bias tee 740 may be implemented per bias tee 330 or 500 previously discussed to combine the RF signal from the output of the tunable impedance matching circuit 730 with the bias current I_{BIAS} generated by the HID laser bias current source 760 to output the RF modulation signal V_{TXRF3} and the bias current I_{BIAS} for the HID laser. As previously discussed, the capacitance of capacitor C3 and inductance of inductor L3 of the bias tee 740 (See e.g., FIG. 6) may be set to improve or optimize the complex impedance Z2 at the output of the tunable impedance matching circuit 730 over the inherent impedance ZH of the HID laser based on the operating RF frequency of the RF2O driver 700.

FIG. 8 illustrates a schematic diagram of an example standing wave ratio (SWR) sensor 800 in accordance with another aspect of the disclosure. The SWR sensor 800 may be an example implementation of the SWR sensor 710 of RF2O driver 700.

The SWR sensor 800 includes a directional coupler 810, a diode D1, a resistor RL, and an optional attenuation pad 805. The optional attenuation pad 805 (e.g., a three (3) decibel (dB) pad), which may be employed to protect the PA, may be coupled between the PA and the directional coupler 810. The directional coupler 810 (e.g., first and second ports P1 and P2) is coupled between the PA or the PAD 805 and the configurable RF transformer chain 720. The directional coupler 810 is configured to route a sample/portion (e.g., −10 dB) of the RF signal V_{TXRF2} to a third port P3 coupled to the anode of the diode D1, where its cathode may be coupled to ground. The diode D1 is configured to generate the signal S_{SWR} at the third port P3 of the directional coupler 810. The remaining portion of the RF signal V_{TXRF2} propagates between the first and second ports P1 and P2 to the configurable RF transformer chain 720.

If the impedance transformation causes an impedance mismatch between the PA and the configurable RF transformer chain 720, the signal S_{SWR} may include standing waves created by such impedance mismatch. The ratio of the maximum to minimum voltages of the standing waves is related to the impedance mismatch. The third port P3 of the directional coupler 810 is coupled to the input of the control circuit 750 to provide the signal S_{SWR} thereto. The resistor RL terminates a fourth port P4 of the directional coupler 810 by being coupled between the fourth port P4 and ground.

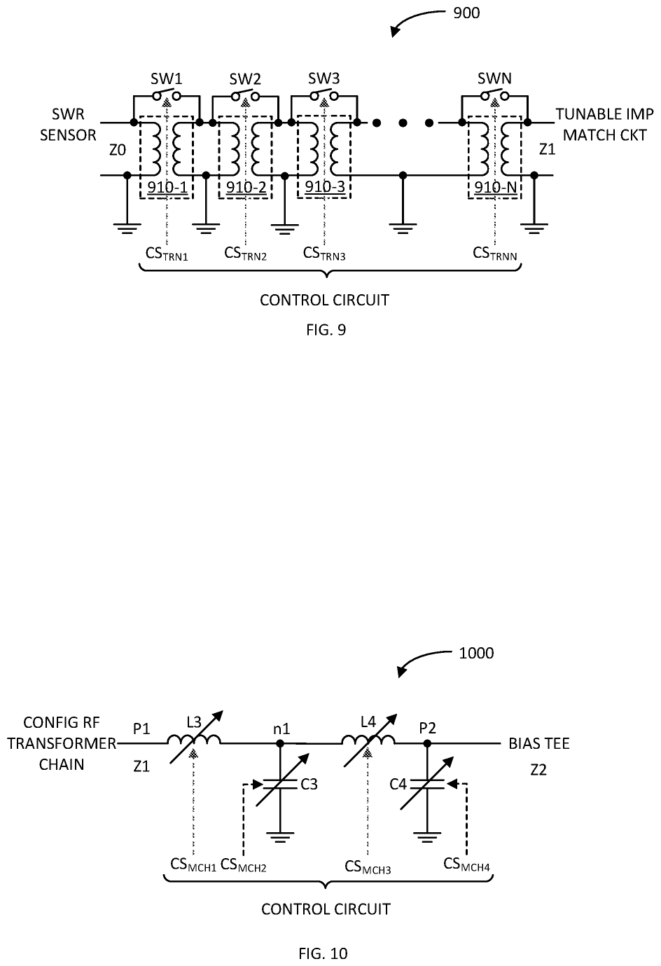

FIG. 9 illustrates a schematic diagram of an example configurable radio frequency (RF) transformer chain 900 in accordance with another aspect of the disclosure. The RF transformer chain 900 may be an example implementation of the configurable RF transformer chain 720 of the RF2O driver 700 previously discussed.

The configurable RF transformer chain 900 includes a set of cascaded RF transformers 910-1 to 910-N, where N is an integer of two (2) or more. Although not shown for simplicity purposes, the configurable RF transformer chain 900 may include the input transmission line 420-0, the set of one or more transmission lines 420-1 to 420-N−1, and the output transmission line 420-N of RF transformer chain 400 in the same or similar configuration. The configurable RF transformer chain 900 further includes a set of bypass switching devices SW1 to SWN coupled across the primary and secondary windings of the cascaded RF transformers 910-1 to 910-N, respectively. The set of switching devices SW1 to SWN are coupled to respective outputs of the control circuit 750 to receive therefrom the control signals CS_{TRN1} to CS_{TRNN} for controlling the on/closed and off/open states of the set of switching devices SW1 to SWN, respectively. If any of the switching devices are off/closed, the corresponding RF transformer is bypassed; or conversely, if any of the switching devices are off/open, the corresponding RF transformer is not bypassed.

As previously discussed, each of the cascaded RF transformers 910-1 to 910-N may be implemented with a set of turns ratios to effectuate the impedance transformation between the output of the PA (e.g., ZPA=Z0=50Ω) and the input of the impedance matching circuit 320 (e.g., Z1=1.56Ω), respectively. As an example, each of the cascaded RF transformers 910-1 to 910-N may be configured with substantially the same turns ratio (e.g., one half (1/2)). In such case, if N=5, then the RF transformers 910-1 to 910-5 may transform the ZPA=Z0=50Ω impedance at the output of the PA to the Z1=1.56Ω impedance at the input of the impedance matching circuit 320 (e.g., 50Ω/2⁵=50/32=1.56Ω). However, it shall be understood that the RF transformers 910-1 to 910-N may be configured with different turns ratios or a mix of the same and different turns ratios.

As previously discussed, the set of control signals CS_{TRN1} to CS_{TRNN} may control the bypassing of the set of cascaded RF transformers 910-1 to 910-N of the RF transformer chain 720. As the number of cascaded RF transformers 910-1 to 910-N not bypassed sets the effective turns ratio NE1/NE2 of the transformer chain 900, whereas the bypassed transformers do not set the effective turns ratio NE1/NE2, the control circuit 750 is able to tune the configurable RF transformer chain 900 to control the impedance transformation between Z0 and Z1 by reducing the signal S_{SWR}. As an example, if the substantially real impedance Z1 at the output of the configurable RF transformer chain 720 is 3.13Ω, and there are five (5) RF transformers in the chain, the control circuit 750 may generate the control signal CS_{TRN5} to bypass RF transformer 910-5, where the remaining four (4) RF transformers 910-1 to 910-4, each having a turns ratio of one half (1/2), are able to transform the Z1=3.13Ω to the Zo=50Ω (e.g., 50Ω/2⁴=50Ω/16=3.13Ω), where 24 or 16 is the effective turns ratio of the configurable RF transformer chain 900.

FIG. 10 illustrates a schematic diagram of an example tunable impedance matching circuit 1000 in accordance with another aspect of the disclosure. The tunable impedance matching circuit 1000 may be an example implementation of the tunable impedance matching circuit 730 of RF2O driver 700 previously discussed.

In particular, the impedance matching circuit 1000 includes a first variable/programmable inductor L3 coupled between a first (input) port P1 and a node n1. The impedance matching circuit 1000 further includes a first variable/programmable capacitor C3 coupled between the node n1 and ground. Further, the impedance matching circuit 1000 includes a second inductor L4 coupled between the node n1 and a second (output) port P2. The impedance matching circuit 1000 also includes a second variable/programmable capacitor C4 coupled between the second (output) port P2 and ground. The second (output) port may be coupled to the input of the bias tee 740.

The first and second variable/programmable inductors L3 and L4 are coupled to outputs of the control circuit 750, respectively. In this regard, the inductances of inductors L3 and L4 are variable/programmable based on control signals CS_{MCH1} and CS_{MCH3} generated by the control circuit 750, respectively. Similarly, the first and second variable/programmable capacitors C3 and C4 are coupled to the outputs of the control circuit 750, respectively. In this regard, the capacitance of capacitors C3 and C4 are variable/programmable based on control signals CS_{MCH2} and CS_{MCH4} generated by the control circuit 750, respectively. Via the control signals CS_{MCH1} to CS_{MCH4}, the inductances of inductors L3 and L4 and the capacitances of capacitors C1 and C2 may be set to effectuate the transformation of the complex impedance Z2 at the input of the bias tee 740 to the substantially real impedance Z1 at the output of the configurable RF transformer chain 720. It shall be understood that the impedance matching circuit 1000 may be implemented in different manners to perform the desired impedance transformation.

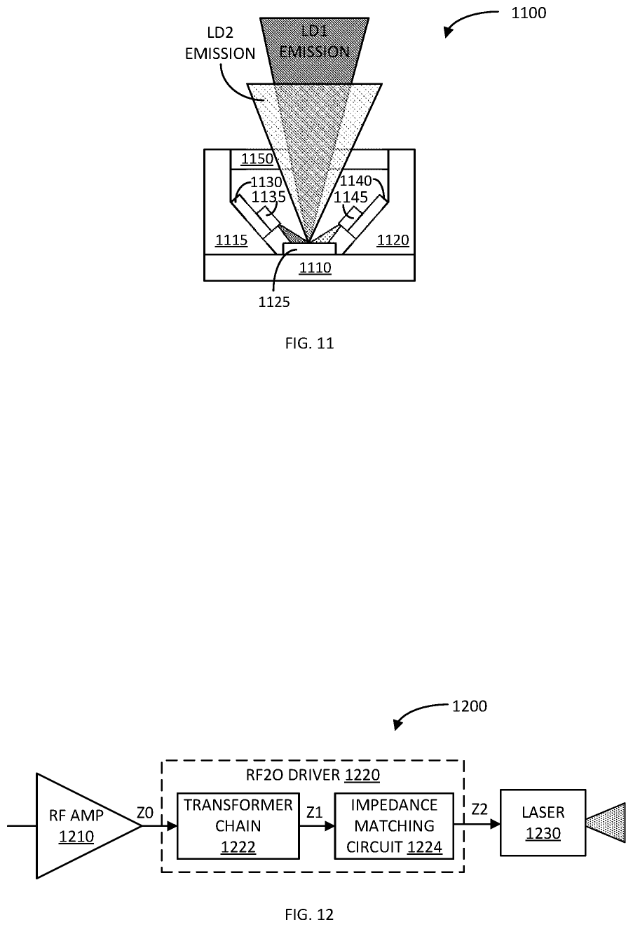

FIG. 11 illustrates a side view of an example high-intensity diffused (HID) laser 1100 in accordance with another aspect of the disclosure. The HID laser 1100 may be an example implementation of the HID laser 274.

The HID laser 1100 includes a housing or enclosure including a base 1110, opposing sidewalls 1115 and 1120 mounted over a peripheral portion of the base 1110, and a laser transparent or semi-transparent cover 1150 mounted over the sidewalls 1115 and 1120. The opposing sidewalls 1115 and 1120 include inner inclined portions upon which laser diode mounts 1130 and 1140 are mounted. The HID laser 1100 includes a pair of laser diodes 1135 and 1145 mounted on the laser diode mounts 1130 and 1140, respectively. The HID laser 1100 further includes a diffuser (e.g., a phosphor diffuser) 1125 mounted centrally over the base 1110.

The laser diodes 1135 and 1145, mounts 1130 and 1140, and inclined portions of the opposing sidewalls 1115 and 1120 are configured so that the laser energy LD1 and LD2 emitted by the laser diodes 1135 and 1145, as indicated by the respective darker and lighter shade emissions, strike the top surface of the diffuser 1125. The diffused laser energy LD1 and LD2 reflected by the diffuser 1125 emanate in a dispersive vertical direction through the laser transparent or semi-transparent cover 1150. The diffused laser energy LD1 and LD2 may have different angles of dispersion, where, in this example, the LD2 emission has a wider dispersion than the LD1 emission.

The laser diodes 1135 and 1145 may be implemented to generate the same or different wavelengths lasers LD1 and LD2. For example, the laser diode 1135 may be a blue laser diode, and the laser diode 1145 may be an infrared (IR) laser diode. With regard to the various implementation of the RF2O drivers 272, 300, and 700, one of the laser diodes (e.g., the blue laser diode 1135) may be used to generate the transmit optical signal O_{TX}, whereas the other laser diode (e.g., the IR laser diode 1145) may be unused or used for other purposes. However, it shall be understood that both laser diodes 1135 and 1145 may be implemented to generate one or more distinct transmit optical signals.

FIG. 12 illustrates a block diagram of an example radio frequency to optical (RF2O) interface 1200 in accordance with another aspect of the disclosure. The RF2O interface 1200 includes a radio frequency (RF) amplifier 1210, and an RF-to-optical (RF2O) driver 1220. The RF2O driver 1220, in turn, includes a transformer chain 1222 including a set of cascaded RF transformers, and an impedance matching circuit 1224 coupled in series with the transformer chain 1222 between the RF amplifier 1210 and a laser 1230.

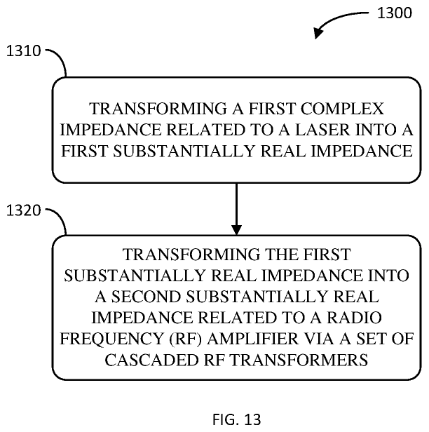

FIG. 13 illustrates a flow diagram of an example method 1300 of impedance matching an output impedance of a radio frequency (RF) amplifier to an input impedance of a diffused laser in accordance with another aspect of the disclosure.

The method 1300 includes transforming a first complex impedance related to a diffused laser into a first substantially real impedance (block 1310). Examples of means for transforming a first complex impedance related to a diffused laser into a first substantially real impedance includes any of the impedance matching circuits described herein. The method 1300 further includes transforming the first substantially real impedance into a second substantially real impedance related to a radio frequency (RF) amplifier via a set of cascaded RF transformers (block 1320). Examples of means for transforming the first substantially real impedance into a second substantially real impedance related to a radio frequency (RF) amplifier via a set of cascaded RF transformers include any of the transformer chains described herein.

The method 1300 may further include providing an RF signal and a bias current to the diffused laser while simultaneously transforming a second complex impedance related to the diffused laser into the first complex impedance. Examples of means for providing an RF signal and a bias current to the diffused laser while simultaneously transforming a second complex impedance related to the diffused laser into the first complex impedance include any of the bias tees described herein.

Additionally, the method 1300 may include sensing a standing wave ratio (SWR) at a node between the RF amplifier and the set of cascaded RF transformer, and adjusting at least one of the transforming of the first complex impedance into the first substantially real impedance or the transforming of the first substantially real impedance into the second substantially real impedance based on the sensing of the SWR. Examples of means for sensing a standing wave ratio (SWR) at a node between the RF amplifier and the set of cascaded RF transformer include any of the SWR sensors described herein. Examples of means for adjusting at least one of the transforming of the first complex impedance into the first substantially real impedance or the transforming of the first substantially real impedance into the second substantially real impedance based on the sensing of the SW include any of the control circuits described herein.

The following provides an overview of aspects of the present disclosure:

Aspect 1: An apparatus, comprising: a radio frequency (RF) amplifier; and an RF-to-optical (RF2O) driver, comprising: a transformer chain including a set of cascaded RF transformers; and an impedance matching circuit coupled in series with the transformer chain between the RF amplifier and a laser.

Aspect 2: The apparatus of aspect 1, wherein the transformer chain is configured to impedance transform a first substantially real impedance at the input of the impedance matching circuit into a second substantially real impedance at the output of the RF amplifier based on an effective turns ratio of the set of cascaded RF transformers, wherein the second substantially real impedance is greater than the first substantially real impedance.

Aspect 3: The apparatus of aspect 2, wherein the second substantially real impedance is substantially 50 ohms.

Aspect 4: The apparatus of aspect 2 or 3, wherein the impedance matching circuit is configured to impedance transform a first complex impedance into the first substantially real impedance.

Aspect 5: The apparatus of any one of aspects 1-4, wherein the impedance matching circuit is configured as a low pass filter (LPF).

Aspect 6: The apparatus of any one of aspects 1-5, wherein the impedance matching circuit comprises at least one series inductor and at least one shunt capacitor.

Aspect 7: The apparatus of any one of aspects 1-6, wherein the RF2O driver further comprises: a bias tee including first and second ports coupled between the impedance matching circuit and the laser; and a current source coupled to a third port of the bias tee.

Aspect 8: The apparatus of aspect 8, wherein: the current source is configured to generate a bias current for the laser; and the bias tee is configured to: receive an RF signal from the impedance matching circuit at the first port; receive the bias current from the current source at the third port; and combine the RF signal with the bias current at the second port.

Aspect 9: The apparatus of any one of aspects 7 or 8, wherein the bias tee comprises: an inductor coupled between the first and second ports; and a capacitor coupled between the third and second ports.

Aspect 10: The apparatus of any one of aspects 1-9, wherein the RF2O driver further comprises: a standing wave ratio (SWR) sensor including first and second ports coupled between the RF amplifier and the transformer chain; a control circuit including an input coupled to a third port of the SWR sensor.

Aspect 11: The apparatus of aspect 10, wherein the SWR sensor is configured to generate a signal related to a standing wave ratio (SWR) at the second port of the SWR sensor; and the input of the control circuit is configured to receive the SWR signal.

Aspect 12: The apparatus of aspect 11, wherein: the control circuit is configured to generate at least one control signal based on the SWR signal; and the transformer chain is configured to receive the at least one control signal.

Aspect 13: The apparatus of aspect 12, wherein at least one of the set of cascaded RF transformers of the transformer chain is bypassable based on the at least one control signal, respectively.

Aspect 14: The apparatus of aspect 12 or 13, wherein an effective turns ratio of the transformer chain is based on the at least one control signal.

Aspect 15: The apparatus of any one of aspects 11-14, wherein: the control circuit is configured to generate at least one control signal based on the SWR signal; and the impedance matching circuit is configured to transform a complex impedance at an output of the impedance matching circuit into a substantially real impedance at an input of the impedance matching circuit based on the at least one control signal.

Aspect 16: The apparatus of aspect 15, wherein the impedance matching circuit includes at least one inductor or capacitor whose inductance or capacitance is variable based on the at least one control signal, respectively.

Aspect 17: The apparatus of any one of aspects 1-16, further comprising a resistor coupled between the transformer chain and the impedance matching circuit.

Aspect 18: The apparatus of any one of aspects 1-17, further comprising a resistor coupled in parallel with the impedance matching circuit.

Aspect 19: The apparatus of any one of aspects 7-18, further comprising a resistor coupled between the impedance matching circuit and the bias tee.

Aspect 20: The apparatus of any one of aspects 7-19, further comprising further comprising a resistor coupled in parallel with the bias tee.

Aspect 21: A method, comprising: transforming a first complex impedance related to a diffused laser into a first substantially real impedance; and transforming the first substantially real impedance into a second substantially real impedance related to a radio frequency (RF) amplifier via a set of cascaded RF transformers.

Aspect 22: The method of aspect 21, further comprising providing an RF signal and a bias current to the diffused laser while simultaneously transforming a second complex impedance related to the diffused laser into the first complex impedance.

Aspect 23: The method of aspect 21 or 22, further comprising: sensing a standing wave ratio (SWR) at a node between the RF amplifier and the set of cascaded RF transformer; and adjusting at least one of the transforming of the first complex impedance into the first substantially real impedance or the transforming of the first substantially real impedance into the second substantially real impedance based on the sensing of the SWR.

Aspect 24: An optical communication device, comprising: a modem; one or more frequency upconverting stages coupled to the modem; a local oscillator (LO) coupled to the one or more frequency upconverting stages; a radio frequency (RF) amplifier coupled to the one or more frequency upconverting stages; a diffused laser; and an RF-to-optical (RF2O) driver, comprising: a transformer chain including a set of cascaded RF transformers; and an impedance matching circuit coupled in series with the transformer chain between the RF amplifier and the diffused laser.

Aspect 25: The optical communication device of aspect 24, further comprising an optical receiver, a low noise amplifier (LNA) coupled to the optical receiver, and one or more frequency downconverting stages coupled to the LNA, the LO, and the modem.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a radio frequency (RF) amplifier; and
an RF-to-optical (RF2O) driver, comprising:
a transformer chain including a set of cascaded RF transformers; and
an impedance matching circuit coupled in series with the transformer chain between the RF amplifier and a laser.

2. The apparatus of claim 1, wherein the transformer chain is configured to impedance transform a first substantially real impedance at an input of the impedance matching circuit into a second substantially real impedance at an output of the RF amplifier based on an effective turns ratio of the set of cascaded RF transformers, wherein the second substantially real impedance is greater than the first substantially real impedance.

3. The apparatus of claim 2, wherein the second substantially real impedance is substantially 50 ohms.

4. The apparatus of claim 2, wherein the impedance matching circuit is configured to impedance transform a first complex impedance into the first substantially real impedance.

5. The apparatus of claim 1, wherein the impedance matching circuit is configured as a low pass filter (LPF).

6. The apparatus of claim 1, wherein the impedance matching circuit comprises at least one series inductor and at least one shunt capacitor.

7. The apparatus of claim 1, wherein the RF2O driver further comprises:
a bias tee including first and second ports coupled between the impedance matching circuit and the laser; and
a current source coupled to a third port of the bias tee.

8. The apparatus of claim 7, wherein:
the current source is configured to generate a bias current for the laser; and
the bias tee is configured to:
receive an RF signal from the impedance matching circuit at the first port;
receive the bias current from the current source at the third port; and
combine the RF signal with the bias current at the second port.

9. The apparatus of claim 7, wherein the bias tee comprises:
an inductor coupled between the first and second ports; and
a capacitor coupled between the third and second ports.

10. The apparatus of claim 1, wherein the RF2O driver further comprises:
a standing wave ratio (SWR) sensor including first and second ports coupled between the RF amplifier and the transformer chain; and
a control circuit including an input coupled to a third port of the SWR sensor.

11. The apparatus of claim 10, wherein:
the SWR sensor is configured to generate a signal related to a standing wave ratio (SWR) at the second port of the SWR sensor; and
the input of the control circuit is configured to receive the SWR signal.

12. The apparatus of claim 11, wherein:
the control circuit is configured to generate at least one control signal based on the SWR signal; and
the transformer chain is configured to receive the at least one control signal.

13. The apparatus of claim 12, wherein at least one of the set of cascaded RF transformers is bypassable based on the at least one control signal, respectively.

14. The apparatus of claim 12, wherein an effective turns ratio of the transformer chain is based on the at least one control signal.

15. The apparatus of claim 11, wherein:
the control circuit is configured to generate at least one control signal based on the SWR signal; and
the impedance matching circuit is configured to transform a complex impedance at an output of the impedance matching circuit into a substantially real impedance at an input of the impedance matching circuit based on the at least one control signal.

16. The apparatus of claim 15, wherein the impedance matching circuit includes at least one inductor or capacitor whose inductance or capacitance is variable based on the at least one control signal, respectively.

17. A method, comprising:
transforming a first complex impedance related to a diffused laser into a first substantially real impedance; and
transforming the first substantially real impedance into a second substantially real impedance related to a radio frequency (RF) amplifier via a set of cascaded RF transformers.

18. The method of claim 17, further comprising providing an RF signal and a bias current to the diffused laser while simultaneously transforming a second complex impedance related to the diffused laser into the first complex impedance.

19. The method of claim 17, further comprising:
sensing a standing wave ratio (SWR) at a node between the RF amplifier and the set of cascaded RF transformers; and
adjusting at least one of the transforming of the first complex impedance into the first substantially real impedance or the transforming of the first substantially real impedance into the second substantially real impedance based on the sensing of the SWR.

20. An optical communication device, comprising:
a modem;
one or more frequency upconverting stages coupled to the modem;
a local oscillator (LO) coupled to the one or more frequency upconverting stages;
a radio frequency (RF) amplifier coupled to the one or more frequency upconverting stages;
a diffused laser; and
an RF-to-optical (RF2O) driver, comprising:
a transformer chain including a set of cascaded RF transformers; and
an impedance matching circuit coupled in series with the transformer chain between the RF amplifier and the diffused laser.
